(19) United States
(12) Patent Application Publication
(10) Pub. No.: US 2026/0146312 A1
(43) Pub. Date: May 28, 2026

(54) HIGH RESOLUTION SHADOW MASK GASKET

(71) Applicant: BAE Systems Information and Electronic Systems Integration Inc., Nashua, NH (US)

(72) Inventors: Alexander S. Warren, North Liberty, IA (US); Nathaniel P. Wyckoff, Marion, IA (US); Benjamin Terry, Cedar Rapids, IA (US)

(73) Assignee: BAE Systems Information and Electronic Systems Integration Inc., Nashua, NH (US)

(21) Appl. No.: 18/956,781

(22) Filed: Nov. 22, 2024

(51) Int. Cl. C23C 14/04; C23C 14/22

(52) U.S. Cl. CPC C23C 14/044; C23C 14/22

(57) ABSTRACT

A system, assembly and method of producing an integrated circuit is provided. A shadow mask is adhered to and aligned with a substrate. There is a shadow mask gasket interposed between the shadow mask and the substrate. A thin film material is deposited on the substrate, such as a silicon wafer, through the shadow mask and the shadow mask gasket. The thin film material that is deposited results in a thin film feature having a boundary with a vertical edge.

### TECHNICAL FIELD

The present disclosure generally relates to integrated circuits. Particularly, the present disclosure relates to evaporative deposition on integrated circuit substrates. More particularly, the present disclosure relates to shadow masks and associated shadow mask gaskets.

### BACKGROUND

Vapor deposition is an important factor in silicon integrated circuit (IC) fabrication and related processes, semiconductors, micromechanical electronic devices, sensors, as well as additive microelectronics and advanced microelectronics packaging.

Vapor deposition or thin film processing is a set of processes in which material is transported from a source or target and thin film on a substrate. Such processes comprise sputtering, electron beam evaporation, resistive evaporation, chemical vapor deposition, atomic layer deposition, and others. While this disclosure is mainly focused on thin film processing, some of the principles herein may also apply to thick film processing.

Vapor deposition or thin film processes are patterned by Lift Off, Etching or Shadow Masking.

For Lift Off, a photoresist mask is applied to a substrate utilizing microlithography patterning. A material is bulk deposited. The photoresist is stripped, which lifts off all unwanted deposited materials to produce the desired patterned substrate.

For etching, a material is bulk deposited on a substrate. A photoresist mask is applied to a substrate utilizing microlithography patterning. A wet or dry chemical etch is used to remove unwanted material. The photoresist is stripped to reveal the patterned substrate.

For shadow masking, a mask is produced by forming openings in a thin metal sheet (usually laser patterned or patterned microlithography/electroplating). The substrate is covered with the shadow mask. Thin film material is deposited such that the substrate is patterned by the opening(s) in the shadow mask to form a thin film feature.

Shadow masks, also known as stencils or deposition masks, are used in a wide range of different vacuum-chamber evaporation and sputtering processes, broadly known as vapor deposition or thin film processing to fabricate both simple and complex semiconductors, micro-engineered electronic components and variety of products in the consumer and life science industries.

Shadow masks are made out of thin stainless steel or nickel. A potential drawback to many of these types of shadow masks, or stencils, is that the material can be difficult to machine, their surfaces are difficult to clean and often result in being used only once. Shadow masks and stencils can also be made from glass. Shadow masks are often laser machined.

Processes that utilize photoresist processing can produce small and high resolution patterns but are labor, equipment, and waste stream intensive. Shadow masks traditionally produce low resolution conductive traces due to underspray.

FIG. 1A presents a system using a prior art shadow mask. Substrate 10 comprises a surface feature 12. Shadow mask 14 is formed over surface feature 12, defining at least one open area or aperture 14a, 14b through which a thin film material 18 (represented by the plurality of downward arrows) may be applied to the substrate 10. Underspray results where shadow mask 14 is present at a significant height 20 above the substrate surface 10. Underspray is where the material is sprayed or deposited in the interstitial space (between the substrate 10 and the shadow mask 14) due to imperfect mask engagement. That is, the deposited material 18 “leaks” under the shadow mask and produces sloped portions in undersprayed regions 22 wherever the material falls through the open areas, such as the sides of apertures 14a and 14b in the shadow mask 14.

The result of such underspray is depicted in FIGS. 1A and 1B, which show deposited features 30a and 30b, formed from thin film material 18 showing a poorly defined boundary between the deposited features 30a and 30b and the undersprayed regions 22. The poorly defined boundary is due to the slope of the material in region 22 that spills into the masked regions 25. Such underspray is doubly wasteful of the thin film material. It uses more material than actually necessary as a portion of the material lands under the mask but does not contribute to the function of the feature. Further, edges of deposited features are “blurry” (e.g., not sharp or not vertical, and therefore wider than necessary), so fewer deposited features can be deposited in a given area meaning a lower circuit density on an integrated circuit. No matter how thin the substrate feature is, when using a shadow mask alone, there is some underspray because the shadow mask 14 cannot directly engage the substrate; see FIGS. 1A and 1B.

The width 31 of the undersprayed boundary regions 22 represent the “boundaries” between the masked portions 25 and unmasked portions 14a, 14b of substrate 10. This width 31 is significant because a portion of deposited material 18 reaches the substrate 10 in the interstitial area between shadow mask 14 and substrate 10. Undersprayed boundary regions 22 are shown in FIG. 1B (not to scale). In one example, FIG. 1C also depicts the width 31 and indefiniteness of undersprayed boundary regions 22 between the thin film material 18 in the desired feature and that in the masked area 25, where no thin film material is desired. Also visible is the boundary 31 between the thin film mask aperture 16 and the masked area 25. It is noted in FIG. 1C that the “boundary” is over 50 microns wide out of an entire measured width of 217 microns. FIG. 1C shows a profile showing the sprayed region to the left (32a), the boundary 26 in the center, and the unsprayed region at the right (32b). This underspray is undesirable. Further, the underspray results in the excessive width of boundary 31.

### SUMMARY

To address the problems presented by the undesired underspray in the masked regions, various embodiments of the present disclosure provide a high resolution shadow mask gasket that is a low cost feature (and corresponding method of manufacture) that enables higher resolution features to be fabricated in higher densities compared to traditional shadow mask deposition.

In one aspect, an exemplary embodiment of the present disclosure is a method of producing an integrated circuit comprising: aligning a shadow mask with a substrate, wherein the shadow mask defines an aperture extending therethrough; positioning a shadow mask gasket between the shadow mask and the substrate, wherein when the shadow mask gasket is interposed between the shadow mask and the substrate, an opening defined by the shadow mask gasket is aligned and in registry with the aperture in the shadow mask and the shadow mask gasket surrounds the aperture in the substrate; depositing a thin film material through the aperture and the opening onto the substrate; and forming at least one thin film feature on the substrate, wherein the at least one thin film feature includes at least a first vertical side edge. In this exemplary embodiment or another exemplary embodiment, the method further comprises: adhering the shadow mask gasket to the shadow mask; and adhering the shadow mask gasket to the substrate. In this exemplary embodiment or another exemplary embodiment, the method further comprises: removing the shadow mask and the shadow mask gasket from the substrate. In this exemplary embodiment or another exemplary embodiment, the method further comprises: forming the shadow mask gasket around at least a portion of a periphery of the aperture in the shadow mask. In this exemplary embodiment or another exemplary embodiment, at least a portion of the substrate is exposed through the shadow mask.

In this exemplary embodiment or another exemplary embodiment, the substrate further comprises a surface feature, and the method further comprises contacting the shadow mask with the surface feature. In this exemplary embodiment or another exemplary embodiment, the shadow mask gasket comprises a side that is coplanar with a side of the shadow mask proximate the aperture through which the thin film material is deposited to form a thin film feature. In this exemplary embodiment or another exemplary embodiment, the method further comprises: aligning a second opening of the shadow mask gasket with the shadow mask such that the shadow mask gasket surrounds a second aperture defined in the shadow mask and the second opening is in registry with the second aperture; depositing the thin film material through the second aperture on the substrate; and forming a second thin film feature on the substrate, wherein the second thin film feature includes at least a second vertical side edge. In this exemplary embodiment or another exemplary embodiment, the shadow mask gasket comprises the same height when surrounding the aperture and the second aperture. In this exemplary embodiment or another exemplary embodiment, a first portion of the shadow mask gasket surrounding the aperture comprises a first height, and wherein a second portion of the shadow mask gasket surrounding the at least the second aperture comprises a second height that is different than the first height.

In another aspect, the disclosure provides an assembly, comprising: a shadow mask aligned with a substrate, wherein the shadow mask defines a first aperture; a shadow mask gasket defining a first opening, wherein the shadow mask gasket is interposed between the shadow mask and the substrate; wherein the shadow mask gasket is coupled to, and aligned with, the shadow mask such that the shadow mask gasket surrounds the first aperture and the first opening is in registry with the first aperture; wherein the shadow mask gasket is coupled to the substrate; wherein the first opening is in registry with the first aperture; and wherein a thin film material on the substrate deposited through the first aperture of the shadow mask and through the first opening of the shadow mask gasket in an area located on the substrate forms a thin film feature having a first vertical side edge. In this exemplary embodiment or another exemplary embodiment, the assembly further comprises at least one masked portion defined between the shadow mask and the substrate. In this exemplary embodiment or another exemplary embodiment, the at least one masked portion of the substrate below the shadow mask is devoid of the deposited thin film material. In this exemplary embodiment or another exemplary embodiment, the assembly further comprises at least a second masked portion defined between the shadow mask and the substrate. In this exemplary embodiment or another exemplary embodiment, the assembly further comprises: a second shadow mask gasket that defines a second opening such that the second opening is in registry with the second aperture of the shadow mask. In this exemplary embodiment or another exemplary embodiment, the shadow mask defines a second aperture. In this exemplary embodiment or another exemplary embodiment, the shadow mask gasket defines a second opening such that the second opening is in registry with the second aperture of the shadow mask.

In this exemplary embodiment or another exemplary embodiment, a first portion of the shadow mask gasket surrounds the first aperture and a second portion of the shadow mask gasket, separate from the first portion, surrounds the second aperture defined in the shadow mask. In this exemplary embodiment or another exemplary embodiment, a first portion of the shadow mask gasket surrounding the first aperture comprises a first thickness; and wherein a second portion of the shadow mask gasket surrounding the second aperture comprises a second thickness that is the same as the first thickness. In this exemplary embodiment or another exemplary embodiment, a first portion of the shadow mask gasket surrounding the first aperture comprises a first thickness; and wherein the second portion of the shadow mask gasket surrounding the second aperture comprises a second thickness that is different from the first thickness.

In another aspect, the disclosure provides: a method of producing an integrated circuit comprising: aligning a shadow mask with a substrate, wherein the shadow mask defines an aperture extending therethrough; positioning a shadow mask gasket between the shadow mask and the substrate, wherein when the shadow mask gasket is interposed between the shadow mask and the substrate, an opening defined by the shadow mask gasket is aligned and in registry with the aperture in the shadow mask and the shadow mask gasket surrounds the aperture; depositing a thin film material through the aperture onto the substrate; and forming at least one thin film feature on the substrate, wherein the thin film feature includes a first vertical side edge. In this exemplary embodiment or another exemplary embodiment, the method further comprises: adhering the shadow mask gasket to the shadow mask; and adhering the shadow mask gasket to the substrate. In this exemplary embodiment or another exemplary embodiment, the method further comprises: removing the shadow mask and the shadow mask gasket from the substrate. In this exemplary embodiment or another exemplary embodiment, the method further comprises: applying the shadow mask gasket around a periphery of desired thin film features on the substrate. In this exemplary embodiment or another exemplary embodiment, the method further comprises: forming the shadow mask gasket around at least a portion of a periphery of the aperture in the shadow mask. In this exemplary embodiment or another exemplary embodiment, at least a portion of the substrate is exposed through the shadow mask. In this exemplary embodiment or another exemplary embodiment, the substrate further comprises a surface feature, and the method further comprises contacting the shadow mask with the surface feature. In this exemplary embodiment or another exemplary embodiment, the shadow mask gasket comprises a side that is coplanar with a side of the shadow mask proximate the aperture through which the thin film material is deposited to form a thin film feature. In this exemplary embodiment or another exemplary embodiment, the method further comprises: aligning a second opening of the shadow mask gasket with the shadow mask such that the shadow mask gasket surrounds a second aperture defined in the shadow mask and the second opening is in registry with the second aperture; depositing the thin film material through the second aperture on the first major face of the substrate; and forming a second thin film feature on the substrate, wherein the second thin film feature includes a second vertical side edge. In this exemplary embodiment or another exemplary embodiment, the shadow mask gasket comprises the same height when surrounding the aperture and the second aperture. In this exemplary embodiment or another exemplary embodiment, a first portion of the shadow mask gasket surrounding the aperture comprises a first height, and wherein a second portion of the shadow mask gasket surrounding the at least the second aperture comprises a second height that is different than the first height.

In still another aspect, the disclosure provides an assembly, comprising: a shadow mask adhered to, and aligned with a substrate, wherein the shadow mask defines a first aperture; a shadow mask gasket defining a first opening and interposed between the shadow mask and the substrate; wherein the shadow mask gasket is adhered to, and aligned with, the shadow mask such that the shadow mask gasket surrounds the first aperture and the first opening is in registry with the first aperture; and a thin film material on the substrate deposited through the first aperture of the shadow mask and through the first opening of the shadow mask gasket in an area located on the first major face of the substrate, wherein the thin film material that is deposited through the first aperture and the first opening results in a thin film feature having a first vertical side edge. In this exemplary embodiment or another exemplary embodiment, the shadow mask and the shadow mask gasket define at least one masked portion between the shadow mask and the substrate. In this exemplary embodiment or another exemplary embodiment, the at least one masked portion of the substrate below the shadow mask is devoid of the deposited thin film material. In this exemplary embodiment or another exemplary embodiment, the shadow mask and the shadow mask gasket define at least a second masked portion between the shadow mask and the substrate. In this exemplary embodiment or another exemplary embodiment, the shadow mask defines a second aperture. In this exemplary embodiment or another exemplary embodiment, the shadow mask gasket defines a second opening such that the second opening is in registry with the second aperture of the shadow mask when the shadow mask gasket surrounds the second aperture. In this exemplary embodiment or another exemplary embodiment, a first portion of the shadow mask gasket surrounds the first aperture and the second portion of the shadow mask gasket, separate from the first portion, surrounds the second aperture defined in the shadow mask. In this exemplary embodiment or another exemplary embodiment, a first portion of the shadow mask gasket surrounding the first aperture comprises a first thickness; and the second portion of the shadow mask gasket surrounding the second aperture comprises a second thickness that is the same as the first thickness. In this exemplary embodiment or another exemplary embodiment, a first portion of the shadow mask gasket surrounding the first aperture comprises a first thickness; and the second portion of the shadow mask gasket surrounding the second aperture comprises a second thickness that is different from the first thickness.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1A (FIG. 1A) is a schematic view of a substrate employing a prior art shadow mask method of thin film deposition.

FIG. 1B (FIG. 1B) is a schematic view of a substrate employing a prior art shadow mask method and also depicting the boundary between sprayed and masked substrate.

FIG. 1C (FIG. 1C) is a graphical view of a depth profile across a sprayed substrate employing a prior art shadow mask method.

FIG. 2A (FIG. 2A) is a schematic view of a substrate with surface feature, shadow mask and shadow mask gasket prior to assembly of the foregoing.

FIG. 2B (FIG. 2B) is a schematic view of the shadow mask gasket and shadow mask of FIG. 2A joined together in an assembly, separate from the substrate.

FIG. 2C (FIG. 2C) is a schematic view of the assembly of FIG. 2B joined together with the substrate.

FIG. 2D (FIG. 2D) is a top plan view of the assembly taken in the direction of line 2D-2D shown in FIG. 2C.

FIG. 2E (FIG. 2E) is a schematic view of the assembly of FIG. 2B joined together with the substrate where a thin film material is applied.

FIG. 2F (FIG. 2F) is a schematic view of a finished circuit board with thin film features thereon.

FIG. 3A (FIG. 3A) is a schematic view of a substrate having an irregular surface, and a method of thin film deposition using a shadow mask and shadow mask gasket of the disclosure.

FIG. 3B (FIG. 3B) is a schematic view of a finished circuit having an irregular surface with thin film features thereon.

FIG. 4 (FIG. 4) is a graphical view of a depth profile across a coated substrate employing a shadow mask method of the disclosure.

FIG. 5 (FIG. 5) is a flow chart of a method of producing a finished circuit according to the disclosure.

Similar numbers refer to similar parts throughout the drawings.

### DETAILED DESCRIPTION

Disclosed herein are a method of producing an integrated circuit and the integrated circuit produced by the method. A system for producing the integrated circuit is also disclosed. A method and system for depositing a thin film material on a masked substrate are further disclosed.

Some exemplary products such as electrodes, organic field effect transistors, photovoltaic cells, micro-electro mechanical systems (MEMS) devices, biomedical devices, optical devices, encoder disks and sensors, such as oxygen sensors, air/fuel sensors, NOx sensors, mass air flow (MAF) sensors, manifold absolute pressure (MAP) sensors, intake air temperature (IAT) sensors, and throttle position sensors (TPS), may employ electronic components having substrates that require shadow masks for production. Any application requiring a shadow mask may benefit from the use of a shadow mask gasket for increased precision in depositing a thin film material or thin film material on a substrate. A surface feature is an electric or electronic component having a profile projecting above the upper substrate level such as a capacitor, resistor, inductor, diode, resistor-capacitor (RC) filter, etc.

Generally, a shadow mask is produced by forming openings in a thin metal sheet (usually laser patterned or patterned microlithography/electroplating).

Fabrication of a shadow mask with a contact gasket can be performed in several ways. Mechanical Fabrication is employed to fabricate shadow mask gaskets with larger geometry features by mechanical cutting or laser patterning gasket materials. Shadow mask gaskets can be spun on low modulus polymer or adhesive backed polymer film (cut in situ or cut then applied). Shadow mask gaskets can be formed by Microlithographic Fabrication where low modulus photoresist films can be applied and patterned for designs with small features. Dry/Wet Etch Fabrication is used to laminate low modulus films on a shadow mask then wet or dry chemically etched to produce the required design. Depending on the required resolution, the shadow mask itself can be used as a deposited reactive ion etch (RIE) mask. Shadow masks are reusable and depending on the process they can be periodically cleaned. The thickness and elastic modulus of gasket materials should be tailored to the required resolution and substrate flatness and topology.

Examples of useful materials from which the shadow mask gasket may be produced include: (a) polyimide tape, such as Kapton®, which may have an adhesive such as silicone or acrylic, and which may have a thickness of, for example, for the silicone adhesive: 0.001″ (±0.0001″), 0.002″ (±0.0002″), or 0.005″ (±0.0005″) or a thickness of, for example for the acrylic adhesive: 0.001″ (±0.0003″), 0.002″ (±0.0004″); (b) polyester film which may include a static dissipative coating such as polyethylene terephthalate (PET) which may have a thickness of 0.002″ to 0.005″, for example 0.004″ (±0.0004″), 0.002″ (±0.0002″); (c) polytetrafluoroethylene (PTFE) tape, also sold as Teflon®, having a thickness of 0.004″ to 0.012″, for example a material thickness of 0.003″ and an adhesive thickness of 0.0015″, where the adhesive may be silicone; (d) copper shimstock, for example 110 copper shimstock, which may have a thickness of 0.005″ (±0.0003″), 0.010″ (±0.0005 ″), 0.015″ (±0.0009 ″), 0.020″ (±0.001 ″), or 0.025″ (±0.001 ″); or (e) PI2545 from HD MicroSystems®, which is a non-photosensitive polyimide precursor, which may be used at a thickness of 0.004″ to 0.120″. All measurements in this paragraph and elsewhere herein are exemplary only, and not limiting.

Broadly, a substrate is covered with a shadow mask. Thin film material is deposited such that the substrate is patterned by an aperture in the shadow mask. The shadow mask is removed to reveal desired thin film material patterns on the substrate.

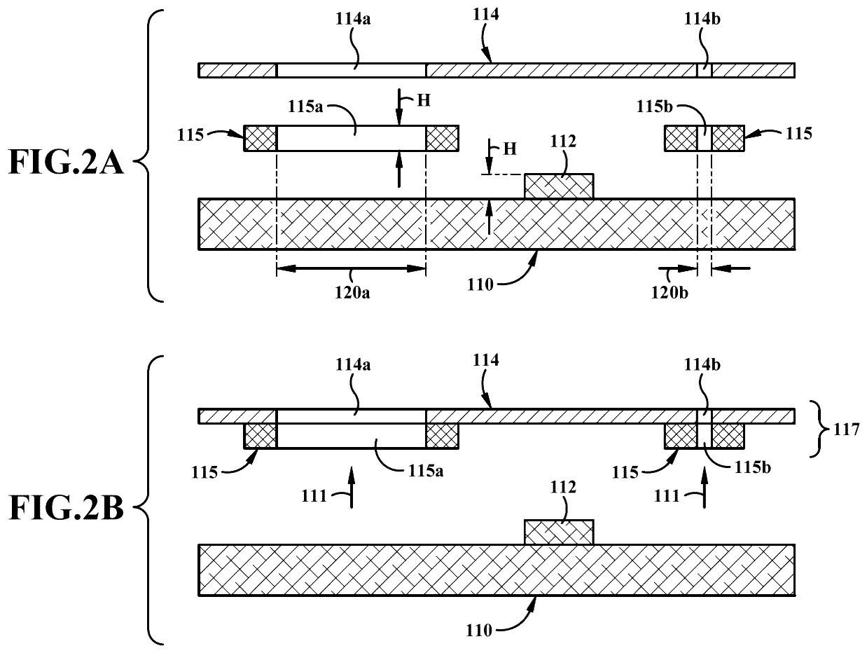

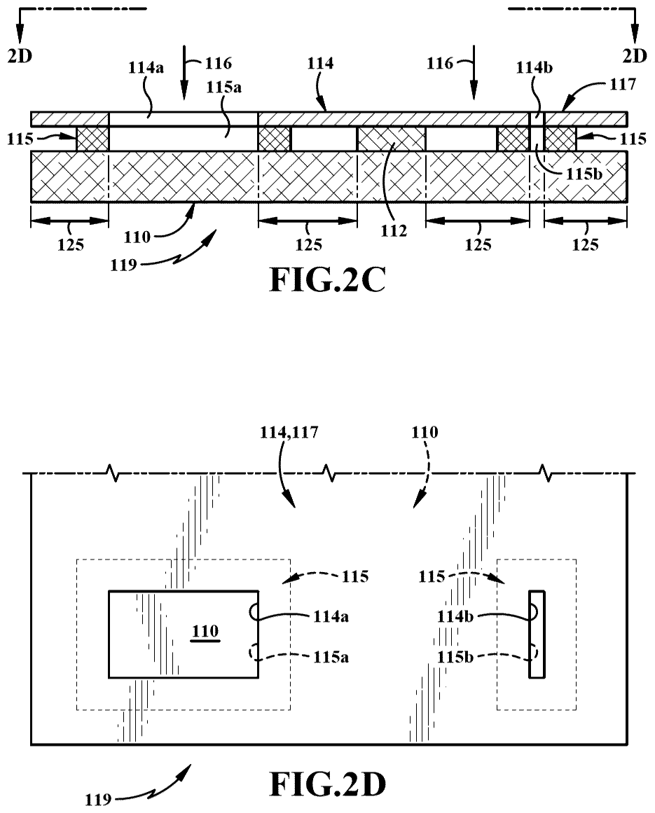

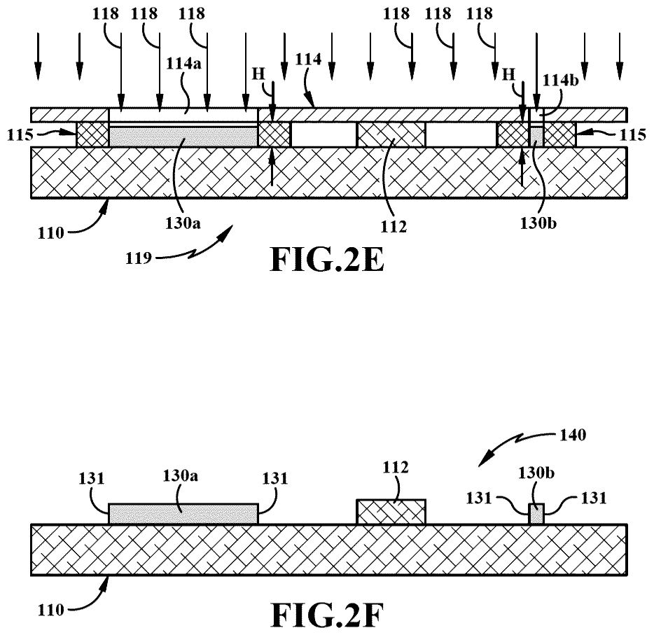

Referring to FIGS. 2A-2F, substrate 110 is provided. Substrate 110 may be a silicon wafer or other electronic materials substrate onto which a conductive trace or other electronic component (sometimes called a “thin film feature”) may be formed or produced as the result of deposition of a thin film material 118. These figures show a side view for convenience and it is understood that the teachings extend to the three dimensional aspects of the substrate 110.

FIG. 2A shows substrate 110 which comprises a surface feature 112 over which a shadow mask 114 is provided. A shadow mask gasket 115 is further provided to define an opening 115a, 115b, through which thin film material 118 is deposited to form a thin film feature 130a, 130b masked areas of the substrate where no thin film material is desired, such as area 125, see FIGS. 2C, 2D. The shadow mask gasket 115 also defines a corresponding diameter or width 120a, 120b to each opening 115a, 115b. In one example, a first diameter 120a of a first opening 115a is greater than a second opening 120b of a second opening 115b. In other examples, diameters 120a, 120b may be any suitable dimension dictated by the width of each thin film feature that is to be included on the substrate 110.

Still referring to FIG. 2A, masked areas, which may mean areas covered with a shadow mask 114, (where no thin film material is desired to be deposited) are indicated by reference number 125. Masked areas 125 may also include a portion of the substrate where a pre-existing surface feature is present under the shadow mask. Below masked areas 125, no thin film material 118 will be deposited, so such areas are devoid of deposited thin film material 118.

Shadow mask 114 defines apertures 114a and 114b while shadow mask gasket 115 defines openings 115a and 115b. Various thin film features 130a, 130b may be formed by deposition of thin film material 118 (see FIG. 2D) through the apertures and openings described in the preceding sentence. Those parts of the substrate 110 above which the shadow mask apertures 114a and 114b as well as shadow mask gasket openings 115a and 115b are the regions of the substrate 110 are where it is desired to deposit thin film material 118. The shadow mask gasket 115 is designed such that opening 115a is in registry with aperture 114a defined in the shadow mask 114. Opening 115b is in registry with aperture 114b defined in the shadow mask 114. Thin film material 118 (shown in FIG. 2D) is precisely deposited onto the substrate where intended, as indicated by thin film features 130a and 130b in FIG. 2D.

Shadow mask 114 is a protective coating or layer that desirably prevents accumulation of thin film material 118 (see FIG. 2D) from reaching substrate 110 in areas covered by shadow mask 114. In FIG. 2A, a substrate 110 with surface feature 112, shadow mask 114, and shadow mask gasket 115, are seen in cross section and unassembled. Shadow mask 114 defines at least one aperture 114a, 114b that is positioned over substrate 110 to permit thin film material 118 is to be added to substrate 110 to form an electronic component or feature. Shadow mask gasket 115 is sized and configured so as to allow shadow mask 114 to rest on surface feature 112 and yet prevent underspray common to the conventional art. While shown as a side view, the shadow mask gasket 115 and shadow mask 114 are aligned so as to define the full periphery of the features to be defined on the substrate 110.

As seen in FIGS. 2A-2F, in particular FIG. 2A, substrate 110 may have one or more surface features 112 projecting therefrom prior to any deposition of a thin film material 118. Surface feature 112 may be a capacitor, resistor, or other component typically used in electronic packaging and/or together with electronic circuitry. As will be described more fully hereinbelow, substrate 110 is to be coated with a thin film material 118. For clarity, surface feature 112 which protrudes from the substrate is not to be confused with the thin film feature(s) (e.g., 130a, 130b) that are to be built up with the thin film material 118.

Thin film features 130a, 130b are formed on portions of the substrate that are not covered by the shadow mask 114 or shadow mask gasket 115 of the disclosure. Stated otherwise, such thin film features 130a, 130b are formed through aperture 114a and opening 115a and/or aperture 114b and opening 115b, while other portions of substrate 110 are not to be so coated. Accordingly, portions of the substrate 110 not to be so coated are masked (e.g., covered or blocked) by a shadow mask 114 and shadow mask gasket 115. The shadow mask 114 is typically a thin sheet of a metal such as stainless steel or nickel, which is laser cut or chemically etched.

It is noted that “spray” is sometimes used to mean deposit or deposition, while “underspray” is used as a shorthand for unwanted deposition in the interstitial space between substrate 110 and shadow mask 114.

FIG. 2B shows the act of adhering or securing shadow mask gasket 115 to shadow mask 114 by motion indicated by the upward arrows labelled 113. Shadow mask gaskets 115 are adhered to surround apertures 114a and 114b on sides of apertures 114a and 114b to prevent underspray. In one embodiment, shadow mask gasket 115 is adhered to completely surround apertures 114a and 114b on all sides of apertures 114a and 114b. In one embodiment, shadow mask gasket 115 is attached to shadow mask 114 prior to placement of shadow masks 114 onto substrate 110.

FIG. 2C shows shadow mask gasket 115 being adhered to shadow mask 114 (prior to securing to substrate 110), which results in assembly 117. Moving assembly 117 in the direction of the downward arrows 116 toward substrate 110 creates assembly 119, which is substrate 110 plus shadow mask gaskets 115 overtopped by shadow mask 114. Masked areas, which may mean areas covered with a shadow mask 114, are indicated by reference number 125. In one example the thickness of the shadow mask gasket 115 is slightly thicker than the desired thickness of the thin film features 130a, 130b. In one example the shadow mask gasket 115 is the same thickness as the surface feature 112. In another example the shadow mask gasket 115 is slightly thicker than the surface feature 112. The alignment of the shadow mark gasket 115 and shadow mask 114 to the substrate 110 is accomplished using alignment techniques known to those skilled in the fabrication industry.

Prior to securing the assembly 117 to the substrate 110 (as shown in FIGS. 2C-2D), the assembly 117 is collectively aligned with the substrate 110 based on the placement of the thin film material 118 on the substrate 110. As best seen in FIGS. 2B-2D, the shadow mask gasket 115 of assembly 117 is aligned with the substrate 110 so that openings 115a, 115b are covering desired portions of the substrate 110 that will receive and create thin film material 118. With such alignment, the shadow mask gasket 115 of assembly 117 is also spaced apart from and/or remote from the surface feature 112 engaged with substrate 110. Such alignment of the assembly 117 prevents any disturbance or physical interaction with the surface feature 112 that may damage or mar said surface feature 112 and prevents any overspray of the thin film material 118 onto said surface feature 112.

In FIG. 2E, the thin film material 118 (indicated by multiple downward arrows) is deposited over the assembly 119 including shadow mask 114, shadow mask gasket 115, and substrate 110. Thin film material 118 is sprayed through apertures 114a and 114b to deposit on substrate 110 thereby producing thin film features 130a and 130b. In FIG. 2D, it is seen that no underspray results because there is a tight seal created by shadow mask gasket 115 between substrate 110 and shadow mask 114. Further, thin film features 130a, 130b are formed where thin film material 118 deposits and accumulates onto substrate 110 through apertures 114a and 114b.

It is noted that the height (profile) of the thin film features 130a, 130b may be any suitable height relative to one or more features of the assembly 117 or the components operably engaged to the substrate 110. As best seen in FIG. 2E, the height (profile) of the thin film features 130a, 130b is less than a height “H” of the shadow mask gasket 115. In one example, the height (profile) of the thin film features 130a, 130b may be equal to the height “H” of the shadow mask gasket 115 if desired. Additionally, it is also noted that the height (profile) of the thin film features 130a, 130b need not be exactly the same height as that of surface feature 112. Accordingly, thin film features 130a, 130b are shown in FIG. 2E as being slightly shorter than surface feature 112. Notably, the deposition and the accumulation of the thin film material 118 may occur in either a single application of thin film material 118 or over multiple “passes” or “runs” of depositing material to accumulate the desired amount of thin film material 118 to create the thin film features 130a, 130b.

The circuit shown in FIG. 2F is obtained by reversing the action in FIG. 2B, that is, lifting or separating assembly 117 from the surface of substrate 110. In one embodiment, the shadow mask 114 and gasket 115 may be separated from the substrate together (e.g., assembly 117) as one unit. In another embodiment, the shadow mask 114 may first be separated and then the shadow mask gaskets 115 be removed from the substrate 110 in a second action. It is noted that in some embodiments, the shadow mask 114 and/or the shadow mask gasket 115 can be reused after depositing the thin film material 118 on substrate 110 which in some cases requires cleaning of shadow mask 114 and shadow mask gasket 115 thereof.

The removal of assembly 117 from substrate 110 yields an integrated circuit 140 that contains thin film features 130a, 130b adhered to substrate 110, which continues to contain surface feature 112, with no underspray.

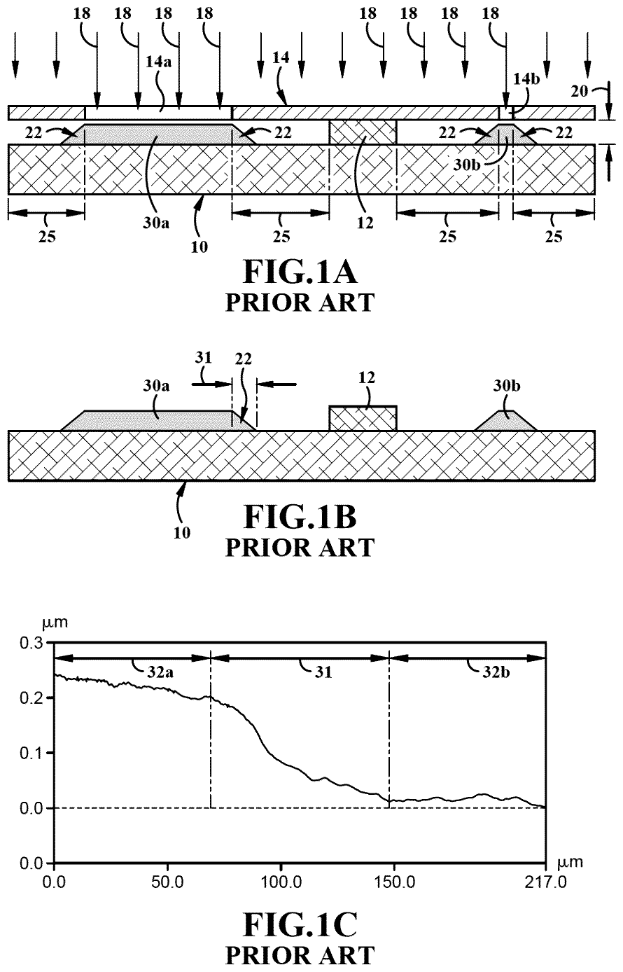

As can be seen in FIG. 2A-FIG. 2F, the usage of shadow mask gasket 115 provides a significant advantage over the prior art shadow masks and methods of fabrication shown in FIG. 1A-FIG. 1C. Particularly, the usage of shadow mask gasket 115 enables boundaries 131 of the thin film features 130a, 130b to have vertical side edges, which is a significant advantage over the prior teachings that resulted in a sloped undersprayed boundary region 22 (see FIG. 1A-1C) when no gasket is utilized. The boundaries 131 on the thin film feature 130a or 130b exhibit vertical edges that are typically within about 5 degrees or less relative to a vertical plane that is perpendicular to horizontal. Stated differently, the boundaries 131 on the thin film features 130a and 130b are either parallel to, or within about 5 degrees from parallel, to a vertical plane that is perpendicular to horizontal. These vertical edges on boundaries 131 are a result of utilizing the shadow mask gasket 115 to prevent underspray. Boundaries 131 are significantly more vertical than the undersprayed boundary region 22 in the prior teachings that has an angle of approximately forty-five degrees or less, which is sloped or inclined relative to horizontal.

The resultant boundaries 131, having vertical edges, may be advantageous to overcome some problems and setbacks that are ordinarily associated with the undersprayed boundary region 22 (see FIG. 1A). For example, the sloped sides resulting from underspray (at undersprayed boundary regions 22) of the thin film feature can cause unintended electrical connections when the thin film extends beyond its intended boundaries and make contact with other parts of the substrate, leading to electrical shorts. The usage of shadow mask gasket 115 to create the boundaries 131 having vertical edges can eliminate or reduce the likelihood of these electrical shorts.

Additionally, the usage of shadow mask gasket 115 to create the boundaries 131 on the thin film feature 130a or 130b provides greater manufacturing precision. The previously described problematic underspray (at undersprayed boundary regions 22) (prior art) can compromise the precision of the thin film pattern. In high-density circuits, even slight deviations can affect the performance and reliability of the device. Precise patterning to produce boundaries 131 having vertical edges on the thin film features 130a or 130b is advantageous to ensure that each component functions correctly and independently.

Still further, the sloped sides resulting from underspray at undersprayed boundary regions 22 of the prior thin film feature can result in increased parasitic capacitance. This unwanted capacitance can degrade the performance of high-frequency circuits by causing signal delays and power losses. The usage of shadow mask gasket 115 to create the boundaries 131 having vertical edges on the thin film features 130a and 130b can reduce the likelihood of parasitic capacitance.

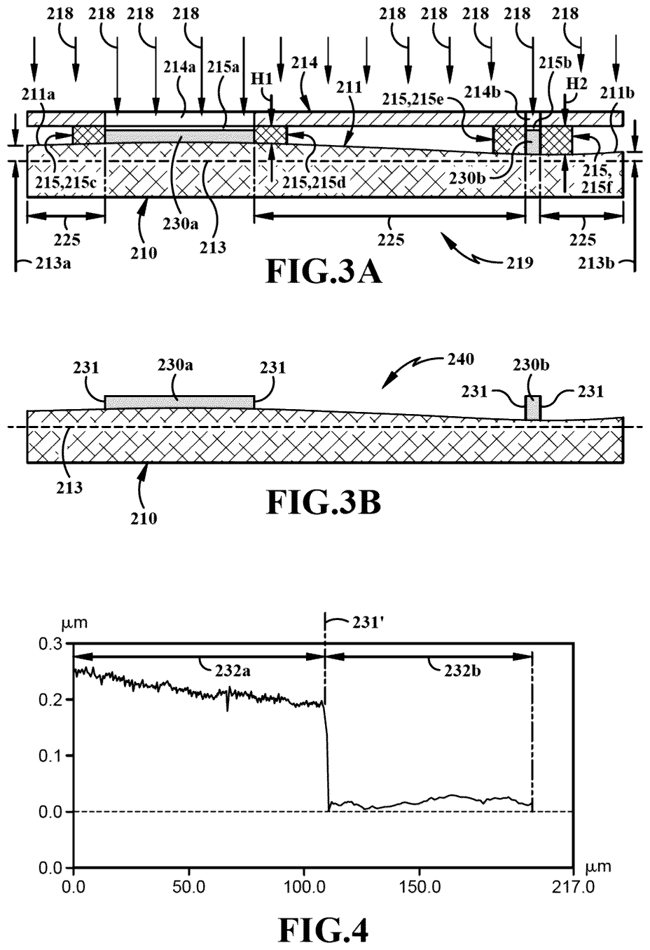

FIG. 3A depicts a substrate 210 with a surface 211, which is irregular, which may be non-flat or curvilinear (e.g., when viewed in an elevational cross section view). Substrate 210 is depicted with a horizontal dashed line, which provides a reference level 213, from which profile heights on substrate 210 are measured. For example, in the embodiment of FIG. 3A, it is seen that the substrate surface is angled with respect to the reference level 213 of substrate 210. Alternatively, the irregular surface 211 of substrate 210 may be jagged, multilayered, stepped, or possess surface features with various depths or profiles, or possess an otherwise non-flat profile. The irregular surface 211 of substrate 210 may alternatively be non-parallel (e.g., sloped) with respect to the reference level 213 of substrate 210 (which in one embodiment is flat and level). Therefore, it would be difficult to apply a shadow mask to such a substrate.

In the exemplary embodiment shown in FIG. 3A, substrate 210 comprises an irregular surface 211 relative to reference level 213. FIG. 3A shows an assembly 219 analogous to assembly 119. Shadow mask gasket 215 is adhered to substrate 210 and defines apertures 215a and 215b therethrough. Shadow mask gasket 215 also defines various portions thereof, labelled separately because each portion 215c, 215d, 215e, 215f has a different profile height measured from reference level 213. In this embodiment, and as seen in FIG. 3A, a first section of shadow mask gasket 215, particularly portions 215c, 215d, defines a first height “H1”, and a second section of shadow mask gasket 215, particularly portions 215e, 215f, defines a second height “H2” that is greater than the first height “H1” due to the non-parallel surface of substrate 210. Shadow mask 214 rests on the shadow mask gasket portions 215c, 215d, 215e, 215f. Together, shadow mask 214 and shadow mask gasket 215 desirably allow thin film material 218 to reach the irregular surface 211 of substrate 210. FIG. 3A differs from FIG. 2D in that the substrate 210 of FIG. 3A does not contain a surface feature (such as 112) however different portions 211a and 211b of irregular surface 211 of substrate 210 have different profile heights from the reference level 213 of substrate 210. It is seen in FIG. 3A that thin film feature 230a comprises a different profile height than thin film surface feature 230b. Accordingly, various portions of shadow mask gasket 215 have different profile heights as seen at 215c, 215d, 215e, 215f. The result is two thin film features 230a and 230b that present the same overall height from reference level 213.

The shadow mask gaskets of the disclosure may be designed and produced to account for irregularities in the substrate surface in order to accommodate a generally flat and planar shadow mask. In FIG. 3A, the substrate surface is sloped where a thin film material is desired to be deposited. Therefore, a shadow mask must be placed over such sloped substrate. Because various portions 215c, 215d, 215e, 215f of shadow mask gasket 215 are tailored to the different topologies of different portions of the substrate, a shadow mask 214, which is flat and level, may be applied to the substrate irrespective of the substrate surface topology. In this context, “flat and level” is defined as parallel to the reference level 213 of substrate 210. Therefore, assembly 219 comprises the tops of thin film features 230a and 230b having the same height. Accordingly, another similar assembly (not shown) could be stacked squarely on top of assembly 219. Any variation of substrate surface topography (e.g., portions 211a, 211b, etc.) can be accommodated by shadow mask gasket 215 disclosed herein.

Considering that various portions 215c, 215d, 215e, 215f of shadow mask gasket 215 may have varying heights across different portions thereof as seen in FIG. 3A, such portions of shadow mask gasket 215 may be fabricated to different thicknesses.

FIG. 3B depicts a final printed circuit produced by the method illustrated in FIG. 3A, which is similar to that in FIG. 2D. The printed circuit of FIG. 3B is analogous to that in FIG. 2F. As seen in FIG. 3B, the irregular surface 211 (shown in FIG. 3A) remains, and thin film features 230a and 230b have different profile heights. Referring again to FIG. 3B, the uppermost surface (e.g., the top) of thin film features 230a and 230b present the same height above reference level 213 after shadow mask 214 and shadow mask gasket 215 are removed therefrom. The usage of shadow mask gasket 215 creates a boundary 231 having a vertical edge.

FIG. 4 depicts a depth profile of a deposited thin film material across a substrate coated with the thin film material, (e.g., a thin film feature) using a shadow mask gasket of the disclosure. In contrast with prior art profile in FIG. 1C, the profile in FIG. 4 representing the disclosed invention, shows a boundary 231, having a vertical edge, between the coating deposited on the unmasked area 232a, and the masked area 232b. In contrast to the wide and indefinite prior art “boundary” in FIG. 1C, which is over 50 microns wide, the boundary 231′ in FIG. 4 is only several microns (<10 or <5 microns) wide. There is little-to-no underspray in the embodiment depicted in FIG. 4C.

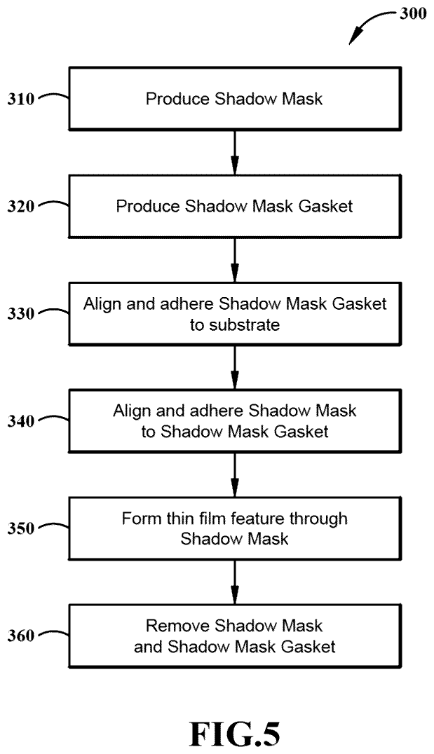

FIG. 5 depicts method steps for producing a shadow mask gasket and applying a thin film material to form a printed circuit on a so-masked substrate. FIG. 5 sets forth a method 300 of forming a printed circuit. First, a shadow mask (SM) is produced at step 310. In one example the shadow mask is metallic that defines cut-outs or apertures that represent the desired thin film features to be deposited on the substrate. It should be noted that the shadow mask may also made or formed from a metal material. Next, a shadow mask gasket (SMG) is produced at step 320. The SMG comprises of one or more types of material that is secured onto an underside of the SM. Examples of suitable materials that make up a SMG discussed herein include, but are not limited to, kapton tape or a similar polyimide film, polyester film or similar polyethylene film, copper shim stock, Teflon tape or a similar polytetrafluoroethylene or PTFE material, and liquid polymide coating products (such as PI 2545 produced by HD MicroSystems™).

Continuing with method 300, the shadow mask gasket is placed around the periphery of each cut-out of the mark. It is noted that in some embodiments, steps 310 and 320 can be reversed in the order of operations. At step 330, the SMG is adhered or secured to, and aligned with, the substrate. This is followed by step 340, where the SM is aligned and adhered or secured to the SMG. It is noted that in some embodiments, steps 330 and 340 may be reversed in order or operation such that step 340 is accomplished before step 330 is accomplished or may be combined into a single step where the SM and the SMG are aligned and secured to the substrate together. A thin film feature is next formed through one or more apertures of the shadow mask, at step 350. Finally, the SM and SMG are removed from the substrate at step 360 to reveal a finished printed circuit.

In other exemplary embodiments, other additional and/or optional steps may be included in method 300. In one example, method 300 may further include steps to secure SMG to SM where SM is a metal foil, pattern the SM and the SMG simultaneously or concurrently to define or more cut-outs or apertures for receiving a thin film material (as discussed herein), and singulate or divide the patterned SM and SMG. In this example, such steps may be further included with or substituted for steps 310, 320, 330, and 340 as discussed above. In another example, method 300 may further include steps to pattern a SM, pattern a SMG, align and secure the SMG to the SM, and to singulate or divide the patterned SM and SMG. In this example, such steps may be further included with or substituted for steps 310, 320, 330, and 340 as discussed above. In yet another example, method 300 may further include steps to align and secure a SM to a sample SMG, form a thin film feature through SM, and remove the SM. In this example, such steps may be further included with or substituted for steps 340, 350, and 360 as discussed above for preexisting or premanufactured SM while omitting steps 310, 320, and 330.

As described herein, aspects of the present disclosure may include one or more electrical other similar secondary components and/or systems therein. The present disclosure is therefore contemplated and will be understood to include any necessary operational components thereof. For example, electrical components will be understood to include any suitable and necessary wiring, fuses, or the like for normal operation thereof. Alternatively, where feasible and/or desirable, various components of the present disclosure may be integrally formed as a single unit.

Unless explicitly stated that a particular shape or configuration of a component is mandatory, any of the elements, components, or structures discussed herein may take the form of any shape. Thus, although the figures depict the various elements, components, or structures of the present disclosure according to one or more exemplary embodiments, it is to be understood that any other geometric configuration of that element, component, or structure is entirely possible. For example, perimeter of the shadow mask gasket can be semi-circular triangular, rectangular or square, pentagonal, hexagonal, heptagonal, octagonal, decagonal, dodecagonal, diamond shaped or another parallelogram, trapezoidal, star-shaped, oval, ovoid, lines or lined, teardrop-shaped, cross-shaped, donut-shaped, heart-shaped, arrow-shaped, crescent-shaped, any letter shape (i.e., A-shaped, B-shaped, C-shaped, D-shaped, E-shaped, F-shaped, G-shaped, H-shaped, I-shaped, J-shaped, K-shaped, L-shaped, M-shaped, N-shaped, O-shaped, P-shaped, Q-shaped, R-shaped, S-shaped, T-shaped, U-shaped, V-shaped, W-shaped, X-shaped, Y-shaped, or Z-shaped), or any other type of regular or irregular, symmetrical or asymmetrical configuration.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Any flowchart and/or block diagrams in the Figures illustrate some exemplary architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc. As another example, “at least one of: A, B, or B” is intended to cover A, B, C, A-B, A-C, B-C, and A-B-C, as well as any combination with multiple of the same item.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A method of producing an integrated circuit comprising:
aligning a shadow mask with a substrate, wherein the shadow mask defines at least one aperture extending therethrough;
providing a shadow mask gasket between the shadow mask and the substrate, wherein when the shadow mask gasket is interposed between the shadow mask and the substrate, at least one opening defined by the shadow mask gasket is aligned with the aperture in the shadow mask;
depositing a thin film material through the aperture and the opening onto the substrate; and
forming at least one thin film feature on the substrate, wherein the at least one thin film feature includes at least a first side edge.

2. The method of claim 1, further comprising:
securing the shadow mask gasket to the shadow mask; and
securing the shadow mask gasket to the substrate.

3. The method of claim 1, further comprising:
removing the shadow mask and the shadow mask gasket from the substrate.

4. The method of claim 1, further comprising:
applying the shadow mask gasket around a periphery of the at least one opening defining all side edges of the at least one thin film feature.

5. The method of claim 1, wherein the step of providing a shadow mask gasket between the shadow mask and the substrate further includes that the shadow mask gasket defines a first height; and
wherein the step of forming at least one thin film feature on the substrate further includes that the at least one thin film feature defines a second height that is equal with the first height.

6. The method of claim 1, wherein the step of providing a shadow mask gasket between the shadow mask and the substrate further includes that the shadow mask gasket defines a first height; and
wherein the step of forming at least one thin film feature on the substrate further includes that the at least one thin film feature defines a second height that is less than the first height.

7. The method of claim 1, wherein the substrate further comprises:
a surface feature, and further comprising contacting the shadow mask with the surface feature.

8. The method of claim 1, wherein the shadow mask gasket comprises a side that is coplanar with a side of the shadow mask proximate the at least one aperture through which the thin film material is deposited to form the at least one thin film feature.

9. The method of claim 8, further comprising:
aligning a second opening of the shadow mask gasket with the shadow mask such that the shadow mask gasket surrounds a second aperture defined in the shadow mask and the second opening aligns with the second aperture;
depositing the thin film material through the second aperture on the substrate; and
forming a second thin film feature on the substrate, wherein the second thin film feature includes at least a second vertical side edge.

10. The method of claim 9, wherein the shadow mask gasket comprises the same height when surrounding the aperture and the second aperture.

11. The method of claim 9, wherein a first portion of the shadow mask gasket surrounding the aperture comprises a first height, and wherein a second portion of the shadow mask gasket surrounding the at least the second aperture comprises a second height that is different than the first height.

12. An assembly, comprising:
a shadow mask configured to align with a substrate, wherein the shadow mask defines a first aperture;
a shadow mask gasket defining a first opening, wherein the shadow mask gasket is configured to be interposed between the shadow mask and the substrate;
wherein the shadow mask gasket is coupled to, and aligned with, the shadow mask such that the shadow mask gasket surrounds a periphery of the first aperture;
wherein the shadow mask gasket is configured to be coupled to the substrate;
wherein the first opening is configured to align with the first aperture; and
wherein when a thin film material is deposited on the substrate through the first aperture of the shadow mask and through the first opening of the shadow mask gasket in an area located on the substrate a thin film feature comprises substantially vertical side edges.

13. The assembly of claim 12, further comprising:
at least one masked portion defined between the shadow mask and the substrate.

14. The assembly of claim 13, wherein the at least one masked portion of the substrate below the shadow mask is devoid of the deposited thin film material.

15. The assembly of claim 12, further comprising:
at least a second masked portion defined between the shadow mask.

16. The assembly of claim 12, further comprising:
a second shadow mask gasket that defines a second opening such that the second opening aligns with the second aperture of the shadow mask.

17. The assembly of claim 12, wherein the shadow mask defines a second aperture.

18. The assembly of claim 17, wherein a first portion of the shadow mask gasket surrounds the first aperture and a second portion of the shadow mask gasket, separate from the first portion, surrounds the second aperture defined in the shadow mask.

19. The assembly of claim 17, wherein a first portion of the shadow mask gasket surrounding the first aperture comprises a first thickness; and wherein a second portion of the shadow mask gasket surrounding the second aperture comprises a second thickness that is the same as the first thickness.

20. The assembly of claim 17, wherein a first portion of the shadow mask gasket surrounding the first aperture comprises a first thickness; and wherein a second portion of the shadow mask gasket surrounding the second aperture comprises a second thickness that is different from the first thickness.
